(19) United States
(12) Patent Application Publication
(10) Pub. No.: US 2025/0101586 A1
(43) Pub. Date: Mar. 27, 2025

(54) HALIDE-FUNCTIONALIZED CYCLOTRISILAZANES AS PRECURSORS FOR DEPOSITION OF SILICON-CONTAINING FILMS

(71) Applicant: Versum Materials US, LLC, Tempe, AZ (US)

(72) Inventors: Manchao Xiao, Carlsbad, CA (US); Haripin Chandra, San Marcos, CA (US); Xinjian Lei, Vista, CA (US); Matthew R. MacDonald, Mission Viejo, CA (US); Mahsa Konh, Carlsbad, CA (US); Pegah Bagheri, Vista, CA (US)

(21) Appl. No.: 18/833,817

(22) PCT Filed: Jan. 25, 2023
(86) PCT No.: PCT/US2023/061303

§ 371 Date: Jul. 26, 2024

Related U.S. Application Data
(60) Provisional application No. 63/303,386, filed on Jan. 26, 2022.

(51) Int. Cl. C23C 16/455; C07F 7/21; C23C 16/34; C23C 16/44

(52) U.S. Cl. CPC C23C 16/45553; C07F 7/21; C23C 16/345; C23C 16/4408; C23C 16/45542

(57) ABSTRACT

Halide-functionalized cyclotrisilazane precursor compounds according to Formulae A and B, and methods using the same, for depositing a silicon-containing film such as silicon oxide, silicon nitride, silicon oxynitride, silicon carbonitride, silicon oxycarbonitride, or carbon-doped silicon oxide via a thermal atomic layer deposition (ALD) or plasma enhanced atomic layer deposition (PEALD) process, and combinations thereof.

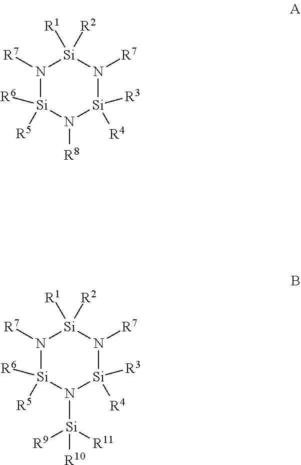

### FIELD OF THE INVENTION

Described herein are halide-functionalized cyclotrisilazane precursor compounds, and compositions comprising the same and methods, for depositing a silicon-containing film such as, without limitation, silicon oxide, silicon nitride, silicon oxynitride, silicon carbonitride, silicon oxycarbonitride, and carbon-doped silicon oxide via a thermal atomic layer deposition (thermal ALD) or plasma enhanced atomic layer deposition (PEALD) process, or a combination thereof. The silicon-containing film may be a stoichiometric or a non-stoichiometric silicon-containing film or material, and may be deposited at one or more deposition temperatures of about 600° C. or lower including, for example, temperatures ranging from about 25° C. to about 300° C.

### BACKGROUND OF THE INVENTION

ALD and PEALD are processes used to deposit, for example, silicon oxide conformal films at low temperature (<600° C.). In both ALD and PEALD processes, the precursor and reactive gas (such as oxygen or ozone) are separately pulsed in a certain number of cycles to form a monolayer of silicon oxide with each cycle. However, silicon oxide deposited at low temperatures using these processes may contain levels of impurities such as, without limitation, nitrogen (N) which may be detrimental in certain semiconductor applications. To remedy this, one possible solution is to increase the deposition temperature to 600° C. or greater. However, at these higher temperatures, conventional precursors employed by semi-conductor industries tend to self-react, thermally decompose, and/or deposit in a chemical vapor deposition (CVD) mode rather than an ALD mode. The CVD mode of deposition has reduced conformality compared to ALD deposition, especially for high aspect ratio structures which are needed in many semiconductor applications. In addition, the CVD mode of deposition has less control of film or material thickness than the ALD mode deposition.

U.S. Pat. Nos. 5,413,813 and 5,424,095 describe the use of different hexamethylcyclotrisilazanes and other silazanes to coat the metal or metal oxide surfaces inside a reactor chamber with a ceramic material at high temperatures in order to prevent coking in subsequent reactor processes involving the pyrolysis of hydrocarbons.

U.S. Pat. No. 10,023,958 B discloses atomic layer deposition of films comprising silicon, carbon and nitrogen using halogenated silicon precursors is discussed. Certain methods involve exposing a substrate surface to a silicon precursor, where the silicon precursor is halogenated with Cl, Br or I, and the silicon precursor comprises a halogenated silane, a halogenated carbosilane, an halogenated aminosilane or a halogenated carbo-silyl amine. Then, the substrate surface can be exposed to a nitrogen-containing plasma or a nitrogen precursor and densification plasma.

U.S. Pat. No. 8,460,753 B discloses a method to form silicon dioxide films that have extremely low wet etch rate in HF solution using a thermal CVD process, ALD process or cyclic CVD process in which the silicon precursor is selected from one of: R¹ₙR²ₘSi(NR³R⁴)₄₋ₙ₋ₘ; and, a cyclic silazane of (R¹R²SiNR³)ₚ, wherein R¹ is an alkenyl or an aromatic, such as vinyl, allyl, and phenyl; R², R³, and R⁴ are selected from H, alkyl with C₁-C₁₀, linear, branched, or cyclic, an alkenyl with C₂-C₁₀ linear, branched, or cyclic, and aromatic; n=1-3, m=0-2; p=3-4

U.S. Pat. No. 9,583,333 B describes the deposition of silicon nitride layer on a substrate by using a remote plasma and hexamethylcyclotrisilazane or other aminosilanes in a plasma-enhanced CVD process at temperatures less than 300° C.

U.S. Pat. No. 9,793,108 B describes the use of a UV-assisted photochemical vapor comprising different silazanes including hexamethylcyclotrisilazane for the purpose of pore-sealing porous low-dielectric films.

US20130330482A1 describes the deposition of carbon-doped silicon nitride films via plasma-enhanced CVD process using vinyl-substituted cyclotrisilazanes or other silazanes as precursors.

There is a need in this art for a process for forming uniform and conformal silicon-containing films such as silicon oxide or silicon nitride having at least one or more of the following attributes: a density of about 2.1 g/cc or greater, a growth rate of 2.0 Å/cycle or greater, low chemical impurity and high conformality in a thermal ALD, a PEALD process or a PEALD-like process using cheaper, reactive, and more stable silicon precursor compounds.

### BRIEF SUMMARY OF THE INVENTION

The instant invention overcomes the above-described needs and others in this art by providing compositions and processes for the deposition of a stoichiometric or nonstoichiometric silicon-containing material or film, such as without limitation, a silicon oxide, a carbon doped silicon oxide, a silicon oxynitride film, silicon nitride, a carbon doped silicon nitride, and a carbon doped silicon oxynitride film at relatively lower temperatures, e.g., at one or more temperatures of 600° C. or lower, in the following deposition process: a PEALD, plasma enhanced cyclic CVD (PECCVD), a PEALD-like process, or an ALD process with an oxygen-containing reactant source, a nitrogen-containing reactant source, or a combination thereof.

In one aspect, there is provided at least one silicon precursor compound selected from the group consisting of Formulae A and B:

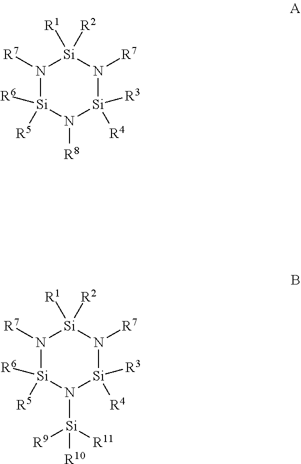

wherein R¹⁻⁶ are each independently selected from the group consisting of hydrogen, methyl, and a halide, including Cl, Br, and I; R⁷ and R⁸ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, and a C₄₋₁₀ heterocyclic group; R⁹⁻¹¹ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, a C₄₋₁₀ heterocyclic group, and a halide, including Cl, Br, and I, wherein two or more of substituents R¹⁻¹¹ may be linked to form a substituted or unsubstituted, saturated or unsaturated, cyclic group, wherein at least one of the substituents R¹⁻⁶ in Formula A is a halide, wherein R⁷ and R⁸ in Formula A cannot both be hydrogen, and wherein at least one of the substituents R⁹⁻¹¹ in Formula B is a halide. The compounds of Formulae A and B are halide-functionalized cyclotrisilazanes having at least 3 silicon atoms and a Si₃N₃ 6-membered ring.

In another embodiment, there is provided a method for depositing a silicon-containing film onto a substrate which comprises the steps of: a) providing a substrate in a reactor; b) introducing into the reactor at least one silicon precursor compound selected from the group consisting of Formulae A and B:

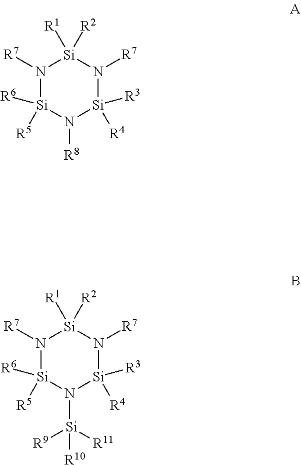

wherein R¹⁻⁶ are each independently selected from the group consisting of hydrogen, methyl, and a halide, including Cl, Br, and I; R⁷ and R⁸ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, and a C₄₋₁₀ heterocyclic group; R⁹⁻¹¹ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, a C₄₋₁₀ heterocyclic group, and a halide, including Cl, Br, and I, wherein two or more of substituents R¹⁻¹¹ may be linked to form a substituted or unsubstituted, saturated or unsaturated, cyclic group, wherein at least one of the substituents R¹⁻⁶ in Formula A is a halide including Cl, Br, or I, wherein R⁷ and R⁸ in Formula A cannot both be hydrogen, and wherein at least one of the substituents R⁹⁻¹¹ in Formula B is a halide including Cl, Br, or I; c) purging the reactor with a purge gas; d) introducing an oxygen-containing or nitrogen-containing source (or combination thereof) into the reactor; and e) purging the reactor with a purge gas, wherein steps b to e are repeated until a desired thickness of film is deposited, and wherein the method is conducted at one or more temperatures ranging from about 25° C. to 600° C.

In some embodiments, the oxygen-containing source employed in the method is a source selected from the group consisting of an oxygen, an oxygen plasma, ozone, a water vapor, water vapor plasma, nitrogen oxide (e.g., N₂O, NO, NO₂) plasma with or without inert gas, a carbon oxide (e.g., CO₂, CO) plasma, and combinations thereof. In certain embodiments, the oxygen-containing source further comprises an inert gas. In these embodiments, the inert gas is selected from the group consisting of argon, helium, nitrogen, hydrogen, and combinations thereof. In an alternative embodiment, the oxygen-containing source does not comprise an inert gas. In yet another embodiment, the oxygen-containing source comprises nitrogen which reacts with the reagents under plasma conditions to provide a silicon oxynitride film.

In some embodiments, the nitrogen-containing source is introduced into the reactor. Suitable nitrogen-containing source gases may include, for example, ammonia, hydrazine, monoalkylhydrazine, dialkylhydrazine, nitrogen, nitrogen/hydrogen, nitrogen/argon plasma, nitrogen/helium plasma, ammonia plasma, nitrogen plasma, nitrogen/hydrogen plasma, organic amines such as tert-butylamine, dimethylamine, diethylamine, isopropylamine, diethylamine plasma, dimethylamine plasma, trimethylamine plasma, ethylenediamine plasma, an alkoxyamine such as ethanolamine plasma and mixtures thereof. In certain embodiments, the nitrogen-containing source comprises an ammonia plasma, a plasma comprising nitrogen and argon, a plasma comprising nitrogen and helium or a plasma comprising hydrogen and nitrogen.

In the embodiments described above and throughout this invention, the inert gas is selected from the group consisting of argon, helium, nitrogen, hydrogen, or combinations thereof. In an alternative embodiment, the oxygen-containing plasma source or nitrogen-containing plasma source does not comprise an inert gas.

One embodiment of the invention relates to uniform and conformal silicon-containing films such as silicon oxide or silicon nitride having at least one or more of the following attributes: a density of about 2.1 g/cc or greater, a growth rate of 2.0 Å/cycle or greater, low chemical impurity, and/or high conformality in a thermal ALD, a PEALD process or a PEALD-like process using cheaper, reactive, and more stable silicon precursor compounds.

The embodiments of the invention can be used alone or in combinations with each other.

### DETAILED DESCRIPTION OF THE INVENTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein are illustrative and shall not limit the scope of the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Described herein are methods related to the formation of a stoichiometric or nonstoichiometric film or material comprising silicon such as, without limitation, a silicon oxide, a carbon-doped silicon oxide film, a silicon oxynitride, a silicon nitride, a carbon-doped silicon nitride, a carbon-doped silicon oxynitride film or combinations thereof with one or more temperatures, of about 600° C. or lower, or from about 25° C. to about 600° C. and, in some embodiments, from 25° C. to about 300° C. The films described herein are deposited in a deposition process such as an atomic layer deposition (ALD) or in an ALD-like process such as, without limitation, a plasma enhanced ALD (PEALD) or a plasma enhanced cyclic chemical vapor deposition process (PECCVD). The low temperature deposition (e.g., one or more deposition temperatures ranging from about ambient temperature to 600° C.) methods described herein provide films or materials that exhibit at least one or more of the following advantages: a density of about 2.1 g/cc or greater, low chemical impurity, high conformality in a thermal ALD, a PEALD process or a PEALD-like process, an ability to adjust carbon content in the resulting film; and/or films have an etching rate of 5 Angstroms per second (Å/sec) or less when measured in 0.5 wt. % dilute HF. For carbon-doped silicon oxide and carbon-doped silicon nitride films, greater than 1% carbon is desired to tune the etch rate to values below 2 Å/sec in 0.5 wt. % dilute HF in addition to other characteristics such as, without limitation, a density of about 1.8 g/cc or greater or about 2.0 g/cc or greater.

The present invention can be practiced using equipment known in the art. For example, the inventive method can use a reactor that is conventional in the semiconductor manufacturing art.

In one embodiment, the silicon precursor composition described herein comprises at least one silicon precursor compound selected from the group consisting of Formulae A and B:

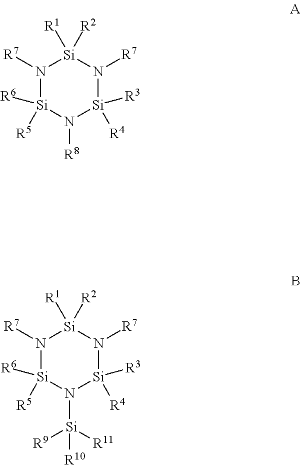

wherein R¹⁻⁶ are each independently selected from the group consisting of hydrogen, methyl, and a halide, including Cl, Br, and I; R⁷ and R⁸ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, and a C₄₋₁₀ heterocyclic group; R⁹⁻¹¹ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, a C₄₋₁₀ heterocyclic group, and a halide, including Cl, Br, and I, wherein two or more of substituents R¹⁻¹¹ may be linked to form a substituted or unsubstituted, saturated or unsaturated, cyclic group, wherein at least one of the substituents R¹⁻⁶ in Formula A is a halide including Cl, Br, or I, wherein R⁷ and R⁸ in Formula A cannot both be hydrogen, and wherein at least one of the substituents R⁹⁻¹¹ in Formula B is a halide including Cl, Br, or I. The compounds of Formulae A and B are halide-functionalized cyclotrisilazanes having at least 3 silicon atoms and a Si₃N₃ 6-membered ring.

In certain embodiments, the halide for R¹⁻⁶ is selected from the group consisting of Cl, Br, and I. In other embodiments, the halide for R⁹⁻¹¹ is selected from the group consisting of Cl, Br, and I. In still other embodiments, the halide for R¹⁻⁶ and R⁹⁻¹¹ is selected from the group consisting of Cl, Br, and I.

In certain embodiments, the halide for at least one of R¹⁻⁶ is CI. In other embodiments, the halide for at least one of R⁹⁻¹¹ is CI. In still other embodiments, the halide for at least one of R¹⁻⁶ and at least one of R⁹⁻¹¹ is C₁.

In one embodiment, each of R¹⁻⁶ is CI. In another embodiment, each of R¹, R³, and R⁵ is C₁. In another embodiment, each of R⁹⁻¹¹ is C₁. In yet another embodiment, each of R¹⁻⁶ and R⁹⁻¹¹ is Cl.

In certain embodiments of the composition described herein further comprises a solvent. Exemplary solvents include, without limitation, ether, tertiary amine, alkyl hydrocarbon, aromatic hydrocarbon, tertiary aminoether, and combinations thereof. In certain embodiments, the difference between the boiling point of the silicon precursor and the boiling point of the solvent is 40° C. or less.

In the formulae above and throughout the description, the term “alkyl” denotes a linear or branched functional group having from 1 to 10 carbon atoms. Exemplary linear alkyl groups include, but are not limited to, methyl, ethyl, propyl, butyl, pentyl, and hexyl groups. Exemplary branched alkyl groups include, but are not limited to, iso-propyl, iso-butyl, sec-butyl, tert-butyl, iso-pentyl, tert-pentyl, iso-hexyl, and neo-hexyl. In certain embodiments, the alkyl group may have one or more functional groups attached thereto such as, but not limited to, an alkoxy group, a dialkylamino group or combinations thereof, attached thereto. In other embodiments, the alkyl group does not have one or more functional groups attached thereto.

In the formulae above and throughout the description, the term “cyclic alkyl” denotes a cyclic functional group having from 3 to 10 carbon atoms. Exemplary cyclic alkyl groups include, but are not limited to, cyclobutyl, cyclopentyl, cyclohexyl, and cyclooctyl groups.

In the formulae above and throughout the description, the term “alkenyl group” denotes a group which has one or more carbon-carbon double bonds and has from 2 to 10 or from 2 to 6 carbon atoms.

In the formulae above and throughout the description, the term “aryl” denotes an aromatic cyclic functional group having from 4 to 10 carbon atoms, from 5 to 10 carbon atoms, or from 6 to 10 carbon atoms. Exemplary aryl groups include, but are not limited to, phenyl, benzyl, chlorobenzyl, tolyl, o-xylyl, 1,2,3-triazolyl, pyrrolyl, and furanyl.

In the formulae above and throughout the description, the term “halide” as that term refers to a substituent means that the substituent is selected from the halogen group on the Period Table of Elements, which includes fluorine, bromine, chlorine, and iodine.

In the formulae above and throughout the description, the term “heterocyclic” means a non-aromatic saturated monocyclic or multicyclic ring system of about 3 to about 10 ring atoms, preferably about 5 to about 10 ring atoms, in which one or more of the atoms in the ring system is/are element(s) other than carbon, for example nitrogen, oxygen or sulfur. Preferred heterocycles contain about 5 to about 6 ring atoms. The prefix aza, oxa or thia before heterocycle means that at least a nitrogen, oxygen or sulfur atom, respectively, is present as a ring atom. The heterocyclic group is optionally substituted.

Exemplary halide-functionalized cyclotrisilazane precursors are listed in Table 1:

TABLE 1

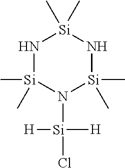

1-chlorosilyl-2,2,4,4,6,6-
hexamethylcyclotrisilazane

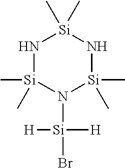

1-bromosilyl-2,2,4,4,6,6-
hexamethylcyclotrisilazane

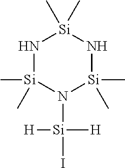

1-iodosilyl-2,2,4,4,6,6-
hexamethylcyclotrisilazane

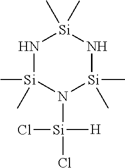

1-dichlorosilyl-2,2,4,4,6,6-
hexamethylcyclotrisilazane

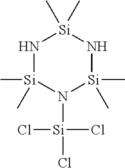

1-trichlorosilyl-2,2,4,4,6,6-
hexamethylcyclotrisilazane

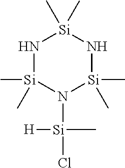

1-chloromethylsilyl-
2,2,4,4,6,6-
hexamethylcyclotrisilazane

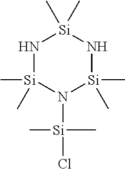

1-chlorodimethylsilyl-
2,2,4,4,6,6-
hexamethylcyclotrisilazane

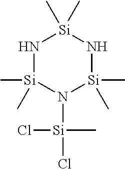

1-dichloromethylsilyl-
2,2,4,4,6,6-
hexamethylcyclotrisilazane

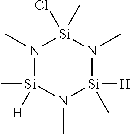

1-chloro-1,2,3,4,5,6-
hexamethylcyclotrisilazane

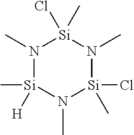

1,2-dichloro-1,2,3,4,5,6-
hexamethylcyclotrisilazane

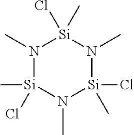

1,3,5-trichloro-1,2,3,4,5,6-
hexamethylcyclotrisilazane

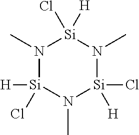

1,3,5-trichloro-2,4,6-
trimethylcyclotrisilazane

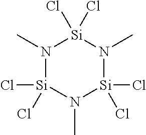

1,1,3,3,5,5-hexachloro-2,4,6-
trimethylcyclotrisilazane

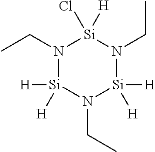

1-chloro-2,4,6-
triethylcyclotrisilazane

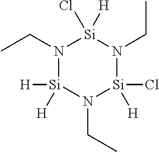

1,3-dichloro-2,4,6-
triethylcyclotrisilazane

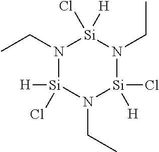

1,3,5-trichloro-2,4,6-
triethylcyclotrisilazane

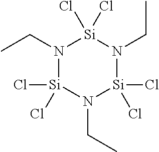 [SMILES: CCN1[Si](Cl)(Cl)N(CC)[Si](Cl)(Cl)N(CC)[Si]1(Cl)Cl]

1,1,3,3,5,5-hexachloro-2,4,6-
triethylcyclotrisilazane

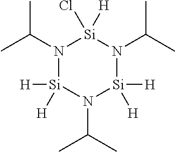 [SMILES: CC(C)N1[SiH2]N(C(C)C)[SiH](Cl)N(C(C)C)[SiH2]1]

1-chloro-2,4,6-tri-iso-
propylcyclotrisilazane

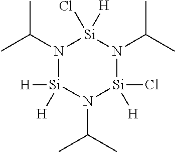 [SMILES: CC(C)N1[SiH2]N(C(C)C)[SiH](Cl)N(C(C)C)[SiH]1Cl]

1,3-dichloro-2,4,6-tri-iso-
propylcyclotrisilazane

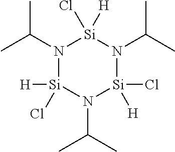 [SMILES: CC(C)N1[SiH](Cl)N(C(C)C)[SiH](Cl)N(C(C)C)[SiH]1Cl]

1,3,5-trichloro-2,4,6-tri-iso-
propylcyclotrisilazane

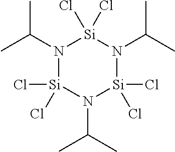 [SMILES: CC(C)N1[Si](Cl)(Cl)N(C(C)C)[Si](Cl)(Cl)N(C(C)C)[Si]1(Cl)Cl]

1,1,3,3,5,5-hexachloro-2,4,6-
tri-iso-propylcyclotrisilazane

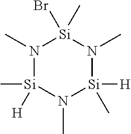

1-bromo-1,2,3,4,5,6-
hexamethylcyclotrisilazane

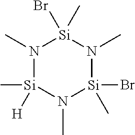

1,3-dibromo-1,2,3,4,5,6-
hexamethylcyclotrisilazane

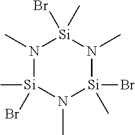

1,3,5-tribromo-1,2,3,4,5,6-
hexamethylcyclotrisilazane

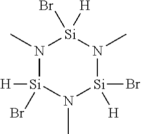

1,3,5-tribromo-2,4,6-
trimethylcyclotrisilazane

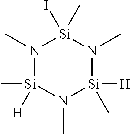

1-iodo-1,2,3,4,5,6-
hexamethylcyclotrisilazane

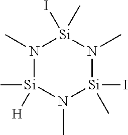

1,3-diiodo-1,2,3,4,5,6-
hexamethylcyclotrisilazane

The silicon precursor compositions described herein, comprising at least one silicon precursor compound selected from the group consisting of Formulae A and B according to the present invention, are preferably substantially free of metal ions such as Li⁺, Na⁺, K⁺, Mg²⁺, Ca²⁺, Al³⁺, Fe²⁺, Fe³⁺, Ni²⁺, Cr³⁺. As used herein, the term “substantially free” as it relates to such metal ions means less than 5 ppm (by weight), preferably less than 3 ppm, more preferably less than 1 ppm, more preferably less than 0.1 ppm, and most preferably less than 0.05 ppm as measured by ICP-MS or other analytical method for measuring metals. In addition, the silicon precursor compositions having Formulae A and/or B have a purity of 98 wt. % or higher, more preferably 99 wt. % or higher as measured by GC when used as precursor to deposit silicon-containing films.

Without intending to be bound by theory, it is believed that the advantage of these precursors over the non-functionalized or amino-functionalized cyclotrisilazanes is that they have at least one Si-halide anchoring unit. This Si—X (X=Cl, Br, or I) bond should be able to react much more readily with an N—H terminated surface to anchor the SiₓN_{y} ring onto the surface conformally and thus grow silicon- and nitrogen-containing films such as silicon nitride or carbon-doped silicon nitride after repeated cycles of [precursor→purge→nitridation→purge] at much lower temperatures than the previously disclosed cyclotrisilazanes. It is also believed that the multiple Si—N bonding network pre-built into the Si₃N₃ ring of these precursors may allow for a more robust and therefore higher quality silicon- and nitrogen-containing film such as for stoichiometric silicon nitride with a formula of Si₃N₄ to be deposited, and at a higher growth per cycle compared to conventional chlorosilane precursors under the same deposition conditions. It is also believed that these halide-functionalized cyclotrisilazane precursors may also be suitable for high growth rate deposition of conformal silicon- and oxygen-containing films such as silicon oxide, carbon-doped silicon oxide, silicon oxynitride, and carbon-doped silicon oxynitride when an oxygen-containing reactant source is used either in conjunction with, in addition to, or instead of a nitrogen-containing reactant source. This dual functionality allows these precursors to be useful for applications in which, for example, multiple alternating layers of silicon nitride and silicon oxide are deposited in a nanolaminate multi-layer structure without changing the silicon-containing precursor.

In addition to conventional methods of synthesizing cyclotrisilazane molecules such as the reaction of chlorosilanes with amines or metal amides to form Si—N bonds, compounds having Formula A or B can be synthesized according to the reactions exemplified by Equations 1 and 2.

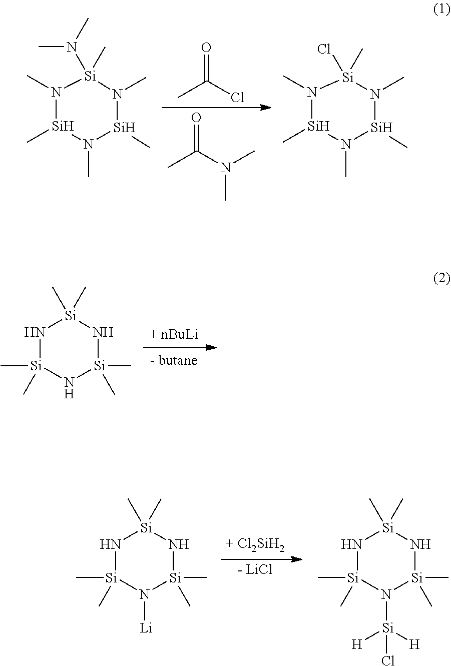

It is clear to one skilled in the art that using other carbonyl chloride, carbonyl bromide, or carbonyl iodide reagents in Equation 1, as well as various other amino-functionalized cyclotrisilazane starting materials allows for the synthesis of numerous combinations of halide-functionalized cyclotrisilazanes having Formula A. It is also clear to one skilled in the art that using other deprotonating agents in in the first step of Equation 2, such as alkali or alkaline earth metals, metal hydrides, or metal alkyls as well as using other simple halidosilane reagents in the second step of Equation 2 such as SiCl₄, Cl₃SiH, Cl₂SiMeH, Cl₃SiMe, Br₂SiH₂, or I₂SiH₂, can afford various other halide-functionalized cyclotrisilazanes having Formula B.

Alternative synthetic methods for generating halide-functionalized cyclotrisilazanes having Formula B include the direct reaction of simple halidosilanes, such as those mentioned above, with N—H functionalized cyclotrisilazane starting materials (optionally in the presence of Lewis base), as exemplified in Equation 3.

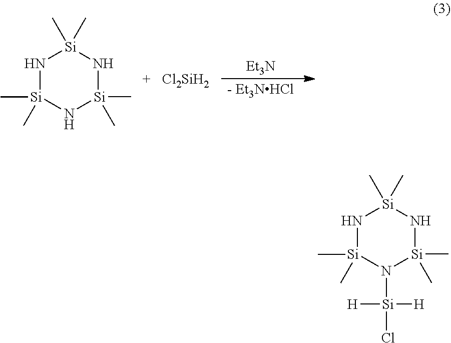

Another alternative method for synthesizing halide-functionalized cyclotrisilazanes having Formulae A or B involves the direct conversion of at least one Si—H bond on a hydride-functionalized cyclotrisilazane to a Si—X bond (X=Cl, Br, I), as exemplified in Equations 4 and 5. Many halogenation reagents known in the literature to perform this transformation which may be used in such halogenation reactions include, but are not limited to Cl₂, Br₂, I₂, HCl, HBr, HI, acetyl halides, alkyl halides, aryl halides, trityl halides, tin halides, antimony halides, mercury halides, iron halides, nickel halides, palladium halides, phosphorus halides, boron halides, N-halidosuccinimides, other organic halides, other main group element-halides, or transition metal halides. Some of these Si—H to Si—X halogenation reactions may require a catalyst.

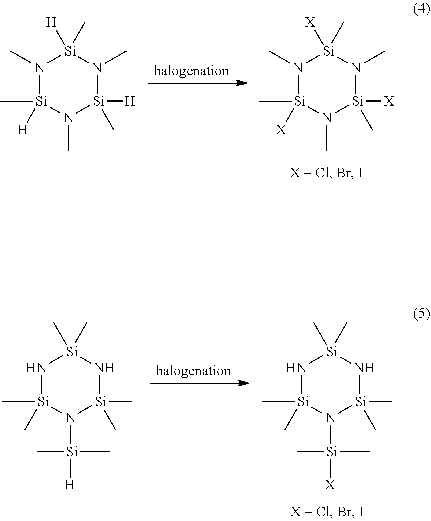

In another embodiment of the present invention, a method is described herein for depositing a silicon-containing film on at least one surface of a substrate, wherein the method comprises the steps of:
a. providing a substrate in a reactor;
b. introducing into the reactor at least one silicon precursor compound having a structure selected from the group consisting of Formulae A and B as defined above;
c. purging the reactor with purge gas;
d. introducing oxygen-containing source comprising a plasma into the reactor; and
e. purging the reactor with a purge gas.

In this method, steps b through e are repeated until a desired thickness of film is deposited on the substrate.

The method of the present invention is conducted via an ALD process that uses ozone or an oxygen-containing source which comprises a plasma wherein the plasma can further comprise an inert gas such as one or more of the following: an oxygen plasma with or without inert gas, a water vapor plasma with or without inert gas, a nitrogen oxide (e.g., N₂O, NO, NO₂) plasma with or without inert gas, a carbon oxide (e.g., CO₂, CO) plasma with or without inert gas, and combinations thereof.

The oxygen-containing plasma source can be generated in situ or, alternatively, remotely. In one particular embodiment, the oxygen-containing source comprises oxygen and is flowing, or introduced during method steps b through e, along with other reagents such as without limitation, the at least one silicon precursor compound and optionally an inert gas.

For those embodiments wherein at least one silicon precursor compound having a structure selected from the group consisting of Formulae A and B is (are) used in a composition comprising a solvent, the solvent or mixture thereof selected does not react with the silicon precursor. The amount of solvent by weight percentage in the composition ranges from 0.5 wt. % by weight to 99.5 wt. % or from 10 wt. % by weight to 75 wt. %. In this or other embodiments, the solvent has a boiling point (b.p.) similar to the b.p. of the silicon precursor compound of Formulae A or B or the difference between the b.p. of the solvent and the b.p. of the silicon precursor of Formulae A or B is 40° C. or less, 30° C. or less, or 20° C. or less, or 10° C. Alternatively, the difference between the boiling points ranges from any one or more of the following end-points: 0, 10, 20, 30, or 40° C. Examples of suitable ranges of b.p. difference include without limitation, 0° C. to 40° C., 20° C. to 30° C., or 10° C. to 30° C. Examples of suitable solvents in the compositions include, but are not limited to, an ether (such as 1,4-dioxane, dibutyl ether), a tertiary amine (such as triethylamine, pyridine, 1-methylpiperidine, 1-ethylpiperidine, N,N′-dimethylpiperazine, N,N,N′,N′-tetramethylethylenediamine), a nitrile (such as acetonitrile or benzonitrile), an alkyl hydrocarbon (such as octane, nonane, dodecane, ethylcyclohexane), an aromatic hydrocarbon (such as toluene, xylene, mesitylene), a tertiary aminoether (such as bis(2-dimethylaminoethyl) ether), or mixtures thereof.

Throughout the description, the term “ALD or ALD-like” refers to a process including, but not limited to, the following processes: a) each reactant including a silicon precursor and a reactive gas is introduced sequentially into a reactor such as a single wafer ALD reactor, semi-batch ALD reactor, or batch furnace ALD reactor; b) each reactant including the silicon precursor and the reactive gas is exposed to a substrate by moving or rotating the substrate to different sections of the reactor and each section is separated by inert gas curtain, i.e., spatial ALD reactor or roll to roll ALD reactor.

In certain embodiments, silicon oxide or carbon-doped silicon oxide films deposited using the methods described herein are formed in the presence of oxygen-containing source comprising ozone, water (H₂O) (e.g., deionized water, purifier water, and/or distilled water), hydrogen peroxide (H₂O₂), oxygen (O₂), oxygen plasma, NO, N₂O, NO₂, carbon monoxide (CO), carbon dioxide (CO₂) and combinations thereof. The oxygen-containing source may be passed through, for example, either an in situ or remote plasma generator to provide an oxygen-containing plasma source comprising oxygen such as an oxygen plasma, a plasma comprising oxygen and argon, a plasma comprising oxygen and helium, an ozone plasma, a water plasma, a nitrous oxide plasma, or a carbon dioxide plasma. In certain embodiments, the oxygen-containing plasma source comprises an oxygen source gas that is introduced into the reactor at a flow rate ranging from about 1 to about 2000 standard cubic centimeters (sccm) or from about 1 to about 1000 sccm. The oxygen-containing plasma source can be introduced for a time that ranges from about 0.1 to about 100 seconds. In one particular embodiment, the oxygen-containing plasma source comprises water having a temperature of 10° C. or greater. In embodiments wherein the film is deposited by a PEALD or a plasma enhanced cyclic CVD process, the precursor pulse can have a pulse duration that is greater than 0.01 seconds (e.g., about 0.01 to about 0.1 seconds, about 0.1 to about 0.5 seconds, about 0.5 to about 10 seconds, about 0.5 to about 20 seconds, about 1 to about 100 seconds) depending on the ALD reactor's volume, and the oxygen-containing plasma source can have a pulse duration that is less than 0.01 seconds (e.g., about 0.001 to about 0.01 seconds).

The deposition methods disclosed herein may involve one or more purge gases. The purge gas, which is used to purge away unconsumed reactants and/or reaction byproducts, is an inert gas that does not react with the precursors, and thereby forming a composition comprising the foregoing. Exemplary purge gases include, but are not limited to, argon (Ar), nitrogen (N₂), helium (He), neon, hydrogen (H₂), and mixtures thereof. In certain embodiments, a purge gas such as Ar is supplied into the reactor at a flow rate ranging from about 10 to about 2000 sccm for about 0.1 to 1000 seconds, thereby purging the unreacted material and any byproduct that may remain in the reactor.

The respective step of supplying the precursors, oxygen source, and/or other precursors, source gases, and/or reagents may be performed by changing the time for supplying them to change the stoichiometric composition of the resulting dielectric film.

Energy is applied to the at least one silicon precursor compound having a structure selected from the group consisting of Formulae A and B, oxygen containing source, or combination thereof to induce reaction and to form the dielectric film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively, a remote plasma-generated process in which plasma is generated outside of the reactor and supplied into the reactor.

The at least one silicon precursor compound may be delivered to the reaction chamber such as a plasma enhanced cyclic CVD or PEALD reactor or a batch furnace type reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor compound. In liquid delivery formulations, the precursor compound described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

As previously mentioned, the purity level of the at least one silicon precursor compound is sufficiently high enough to be acceptable for reliable semiconductor manufacturing. In certain embodiments, the at least one silicon precursor compound described herein comprise less than 2% by weight, or less than 1% by weight, or less than 0.5% by weight of one or more of the following impurities: free amines, free halides or halogen ions, and higher molecular weight species. Higher purity levels of the silicon precursor compound described herein can be obtained through one or more of the following processes: purification, adsorption, crystallization, and/or distillation.

In one embodiment of the method described herein, a plasma enhanced cyclic deposition process such as PEALD-like or PEALD may be used wherein the deposition is conducted using the at least one silicon precursor compound and an oxygen plasma source. The PEALD-like process is defined as a plasma enhanced cyclic CVD process but still provides high conformal silicon-containing films.

In certain embodiments, the gas lines connecting from the precursor canisters to the reaction chamber are heated to one or more temperatures depending upon the process requirements and the container of the at least one silicon precursor compound is kept at one or more temperatures for bubbling. In other embodiments, a solution comprising the at least one silicon precursor compound is injected into a vaporizer kept at one or more temperatures for direct liquid injection.

A flow of argon and/or other gas may be employed as a carrier gas to help deliver the vapor of the at least one silicon precursor compound to the reaction chamber during the precursor pulsing. In certain embodiments, the reaction chamber process pressure is about 50 mTorr to 10 Torr. In other embodiments, the reaction chamber process pressure can be up to 760 Torr (e.g., about 50 mtorr to about 100 Torr).

In a typical PEALD or a PEALD-like process such as a PECCVD process, the substrate such as a silicon oxide substrate is heated on a heater stage in a reaction chamber that is exposed to the silicon precursor compound initially to allow the complex to chemically adsorb onto the surface of the substrate.

A purge gas such as argon purges away unabsorbed excess complex from the process chamber. After sufficient purging, an oxygen-containing source may be introduced into reaction chamber to react with the absorbed surface followed by another gas purge to remove reaction by-products from the chamber. The process cycle can be repeated to achieve the desired film thickness. In some cases, pumping can replace a purge with inert gas or both can be employed to remove unreacted silicon precursor compound.

In this or other embodiments, it is understood that the steps of the methods described herein may be performed in a variety of orders, may be performed sequentially, may be performed concurrently (e.g., during at least a portion of another step), and any combination thereof. The respective step of supplying the precursor compound and the oxygen-containing source, for example, may be performed by varying the duration of the time for supplying them to change the stoichiometric composition of the resulting dielectric film. Also, purge times after precursor or oxidant steps can be minimized to <0.1 s so that throughput is improved.

In one particular embodiment, the method described herein deposits a high quality silicon-containing film such as, for example, a silicon and oxygen-containing film, on a substrate. The method comprises the following steps:
a. providing a substrate in a reactor;
b. introducing into the reactor at least one silicon precursor compound having a structure selected from the group consisting of Formulae A and B described herein;
c. purging the reactor with a purge gas to remove at least a portion of the unabsorbed precursor compound;
d. introducing an oxygen-containing plasma source into the reactor and
e. purging reactor with a purge gas to remove at least a portion of the unreacted oxygen-containing source,
   wherein steps b through e are repeated until a desired thickness of the silicon-containing film is deposited.

Another method disclosed herein forms a carbon doped silicon oxide film using at least one silicon precursor compound having a structure selected from the group consisting of Formulae A and B as defined above plus an oxygen source.

Another exemplary process is described as follows:
a. providing a substrate in a reactor;
b. contacting vapors generated from at least one silicon precursor compound having a structure selected from the group consisting of Formulae A and B as defined above, with or without co-flowing an oxygen source to chemically absorb the precursor compound on the heated substrate;
c. purging away any unabsorbed precursor compound;
d. Introducing an oxygen source on the heated substrate to react with the absorbed precursors; and,
e. purging away any unreacted oxygen source,
   wherein steps b through e are repeated until a desired thickness is achieved.

In another particular embodiment, the method described herein deposits a high quality silicon-containing film such as, for example, a silicon nitride film, on a substrate. The method comprises the following steps:
a. providing a substrate in a reactor;
b. introducing into the reactor at least one silicon precursor compound having a structure selected from the group consisting of Formulae A and B described herein;
c. purging the reactor with a purge gas to remove at least a portion of the unabsorbed precursor compound;
d. introducing a nitrogen-containing plasma source into the reactor and
e. purging the reactor with a purge gas to remove at least a portion of the unreacted nitrogen-containing source,
   wherein steps b through e are repeated until a desired thickness of the silicon-containing film is deposited.

Another exemplary process is described as follows:
a. providing a substrate in a reactor;
b. contacting vapors generated from at least one silicon precursor compound having a structure selected from the group consisting of Formulae A and B as defined above, with or without co-flowing a nitrogen source to chemically absorb the precursor compound on the heated substrate;
c. purging away any unabsorbed precursor compound;
d. Introducing a nitrogen-containing source on the heated substrate to react with the absorbed precursor compound; and,
e. purging away any unreacted nitrogen source,
   wherein steps b through e are repeated until a desired thickness is achieved.

In some embodiments, the method described herein also employs a volatile amine catalyst such as triethylamine, trimethylamine, dimethylamine, methylamine, 4-dimethylaminopyridine, N,N′-dimethylethylenediamine, ethylenediamine, or pyridine which is co-flowed during either the silicon precursor pulse step or the oxygen- and/or nitrogen-containing source pulse step, or during both chemical source pulse steps in order to facilitate reaction of the precursor with the substrate surface and/or the anchored precursor compound with the co-reactant gas.

An exemplary method employing a volatile amine catalyst comprises the following steps:
a. providing a substrate in a reactor;
b. introducing into the reactor at least one silicon precursor compound having a structure selected from the group consisting of Formulae A and B described herein while also introducing into the reactor the volatile amine catalyst such as pyridine;
c. purging the reactor with a purge gas to remove at least a portion of the unabsorbed precursor compound;
d. introducing a nitrogen- and/or oxygen-containing source into the reactor and
e. purging the reactor with a purge gas to remove at least a portion of the unreacted nitrogen- and/or oxygen-containing source,
   wherein steps b through e are repeated until a desired thickness of the silicon-containing film is deposited. Further exemplary methods may comprise introducing the volatile amine catalyst into the reactor during both steps b and d or, alternatively, only during step d.

Various commercial ALD reactors such as single wafer, semi-batch, batch furnace or roll to roll reactor can be employed for depositing the solid silicon oxide, silicon nitride, silicon oxynitride, carbon doped silicon nitride, carbon doped silicon oxynitride, or carbon doped silicon oxide.

Process temperature for the method described herein use one or more of the following temperatures as endpoints: 0° C., 25° C., 50° C., 75° C., 100° C., 125° C., 150° C., 175° C., 200° C., 225° C., 250° C., 275° C., 300° C., 325° C., 350° C., 375° C., 400° C., 425° C., 450° C., 475° C., 500° C., 525° C., 550° C., 575° C., 600° C. Exemplary temperature ranges include, but are not limited to the following: from about 0° C. to about 300° C.; or from about 25° C. to about 300° C.; or from about 50° C. to about 290° C.; or from about 25° C. to about 250° C., or from about 25° C. to about 200° C.

In certain embodiments, the oxygen-containing source is selected from the group consisting of water vapors, ozone, oxygen, hydrogen peroxide, organic peroxides, and mixtures thereof. In other embodiments, the oxygen-containing source is an oxygen-containing plasma source selected from the group consisting of water plasma, oxygen plasma, oxygen/helium plasma, oxygen/argon plasma, nitrogen oxides plasma, carbon dioxide plasma, carbon monooxide plasma, and mixtures thereof. In other embodiments, the nitrogen source is selected from the group consisting of for example, ammonia, hydrazine, monoalkylhydrazine, dialkylhydrazine, nitrogen, nitrogen/hydrogen, nitrogen/argon plasma, nitrogen/helium plasma, ammonia plasma, nitrogen plasma, nitrogen/hydrogen plasma, organic amines such as tert-butylamine, dimethylamine, diethylamine, isopropylamine, diethylamine plasma, dimethylamine plasma, trimethyl plasma, trimethylamine plasma, ethylenediamine plasma, and an alkoxyamine such as ethanolamine plasma, and mixtures thereof. In yet other embodiments, the nitrogen-containing source is a nitrogen-containing plasma source selected from the group consisting of an ammonia plasma, a plasma comprising nitrogen and argon, a plasma comprising nitrogen and helium or a plasma comprising hydrogen and nitrogen source gas, and combination thereof. In this or other embodiments, the method steps are repeated until the surface features are filled with the silicon-containing film. In embodiments wherein water vapor is employed as an oxygen source, the substrate temperature ranges from about −20° C. to about 40° C. or from about −10° C. to about 25° C.

In a still further embodiment of the method described herein, the film or the as-deposited film deposited from ALD, ALD-like, PEALD, or PEALD-like is subjected to a treatment step (post deposition). The treatment step can be conducted during at least a portion of the deposition step, after the deposition step, and combinations thereof. Exemplary treatment steps include, without limitation, treatment via high temperature thermal annealing; plasma treatment; ultraviolet (UV) light treatment; laser; electron beam treatment and combinations thereof to affect one or more properties of the film.

The films deposited with the silicon precursor compound having Formulae A or B described herein, when compared to films deposited with previously disclosed silicon precursor compound under the same conditions, have improved properties such as, without limitation, a relatively lower wet etch rate of the film before the treatment step or a relatively higher density prior to the treatment step. In one particular embodiment, during the deposition process, as-deposited films are intermittently treated. These intermittent or mid-deposition treatments can be performed, for example, after each ALD cycle, after every a certain number of ALD, such as, without limitation, one (1) ALD cycle, two (2) ALD cycles, five (5) ALD cycles, or after every ten (10) or more ALD cycles.

The precursor compounds of Formulae A and B may exhibit a film growth rate of 2.0 Å/cycle or greater.

In an embodiment wherein the film is treated with a high temperature annealing step, the annealing temperature is at least 100° C. or greater than the deposition temperature. In this or other embodiments, the annealing temperature ranges from about 400° C. to about 1000° C. In this or other embodiments, the annealing treatment is conducted in a vacuum (<760 Torr), inert environment, an oxygen containing environment (such as H₂O, N₂O, NO₂ or O₂), or a nitrogen containing environment (such as H₂/N₂, hydrazine, triethylamine, pyridine, or ammonia).

In an embodiment wherein the film is subjected to UV treatment, film is exposed to broad band UV or, alternatively, a UV source having a wavelength ranging from about 150 nanometers (nm) to about 400 nm. In one particular embodiment, the as-deposited film is exposed to UV in a different chamber than the deposition chamber after a desired film thickness is reached.

In an embodiment wherein the film is treated with a plasma, a passivation layer such as SiO₂ or carbon doped SiO₂ is deposited to prevent chlorine and nitrogen contamination to penetrate into film in the subsequent plasma treatment. The passivation layer can be deposited using atomic layer deposition or cyclic chemical vapor deposition.

In an embodiment wherein the film is treated with a plasma, the plasma source is selected from the group consisting of hydrogen plasma, plasma comprising hydrogen and helium, plasma comprising hydrogen and argon. Hydrogen plasma lowers film dielectric constant and boost the damage resistance to following plasma ashing process while still keeping the carbon content in the bulk almost unchanged.

Without intending to be bound by a particular theory, it is believed that the silicon precursor compound having a chemical structure represented by Formulae A or B as defined above can be anchored via reacting a halido group such as chloro with N—H or hydroxyl groups on the substrate surface to provide Si—N—Si or Si—O—Si fragments, thus increasing the growth rate of silicon nitride, silicon carbon nitride, silicon oxide or carbon doped silicon oxide compared to conventional silicon precursors such as bis(tert-butylamino) silane or bis(diethylamino) silane having only one silicon atom. With the halide-functionalized cyclotrisilazanes having Formulae A or B, as many as 3 to 4 silicon atoms can be anchored to the substrate per molecule during a silicon precursor pulse step.

In certain embodiments, the silicon precursor compound having Formulae A or B as defined above can also be used as a dopant for metal containing films, such as but not limited to, metal oxide films or metal nitride films. In these embodiments, the metal containing film is deposited using an ALD or CVD process such as those processes described herein using metal alkoxide, metal amide, or volatile organometallic precursors. Examples of suitable metal alkoxide precursors that may be used with the method disclosed herein include, but are not limited to, group 3 to 6 metal alkoxide, group 3 to 6 metal complexes having both alkoxy and alkyl substituted cyclopentadienyl ligands, group 3 to 6 metal complexes having both alkoxy and alkyl substituted pyrrolyl ligands, group 3 to 6 metal complexes having both alkoxy and diketonate ligands; group 3 to 6 metal complexes having both alkoxy and ketoester ligands.

Examples of suitable metal amide precursors that may be used with the method disclosed herein include, but are not limited to, tetrakis(dimethylamino) zirconium (TDMAZ), tetrakis(diethylamino) zirconium (TDEAZ), tetrakis(ethylmethylamino) zirconium (TEMAZ), tetrakis(dimethylamino) hafnium (TDMAH), tetrakis(diethylamino) hafnium (TDEAH), and tetrakis(ethylmethylamino) hafnium (TEMAH), tetrakis(dimethylamino) titanium (TDMAT), tetrakis(diethylamino) titanium (TDEAT), tetrakis(ethylmethylamino) titanium (TEMAT), tert-butylimino tri (diethylamino) tantalum (TBTDET), tert-butylimino tri (dimethylamino) tantalum (TBTDMT), tert-butylimino tri (ethylmethylamino) tantalum (TBTEMT), ethylimino tri (diethylamino) tantalum (EITDET), ethylimino tri (dimethylamino) tantalum (EITDMT), ethylimino tri (ethylmethylamino) tantalum (EITEMT), tert-amylimino tri (dimethylamino) tantalum (TAIMAT), tert-amylimino tri (diethylamino) tantalum, pentakis (dimethylamino) tantalum, tert-amylimino tri (ethylmethylamino) tantalum, bis(tert-butylimino)bis(dimethylamino) tungsten (BTBMW), bis(tert-butylimino) bis(diethylamino) tungsten, bis(tert-butylimino)bis(ethylmethylamino) tungsten, and combinations thereof. Examples of suitable organometallic precursors that may be used with the method disclosed herein include, but are not limited to, group 3 metal cyclopentadienyls or alkyl cyclopentadienyls. Exemplary Group 3 to 6 metals herein include, but not limited to, Y, La, Ce, Pr, Nd, Sm, Eu, Gd, Tb, Dy, Er, Yb, Lu, Ti, Hf, Zr, V, Nb, Ta, Cr, Mo, and W.

In certain embodiments, the silicon-containing films described herein have a dielectric constant of 6 or less, 5 or less, 4 or less, and 3 or less. In these or other embodiments, the films have a dielectric constant of about 5 or below, or about 4 or below, or about 3.5 or below. However, it is envisioned that films having other dielectric constants (e.g., higher or lower) can be formed depending upon the desired end-use of the film. An example of a silicon-containing film that is formed using the silicon precursor compound having Formula A and/or B and processes described herein has the formulation SiₓO_{y}C_{z}NᵥH_{w} wherein Si ranges from about 10 at. % to about 40 at. %; O ranges from about 0 at. % to about 65 at. %; C ranges from about 0 at. % to about 75 at. % or from about 0 at. % to about 50 at. %; N ranges from about 0 at. % to about 75 at. % or from about 0 at. % to 50 at. %; and H ranges from about 0 at. % to about 50 at. % wherein x+y+z+v+w=100 atomic weight percent, as determined for example, by XPS or other means. Another example of the silicon containing film that is formed using the silicon precursor compound of Formula A and/or B and processes described herein is silicon carbonitride wherein the carbon content is from 1 at. % to 80 at. % measured by XPS. In yet, another example of the silicon containing film that is formed using the silicon precursor compound having Formula A and B and processes described herein is amorphous silicon wherein both sums of nitrogen and carbon contents is <10 at. %, preferably <5 at. %, most preferably <1 at. % measured by XPS. The ratio of nitrogen to silicon ranges from 1.20 to 1.40, preferably 1.25 to 1.35, most preferably 1.27 to 1.34.

As mentioned previously, the method described herein may be used to deposit a silicon-containing film on at least a portion of a substrate. Examples of suitable substrates include but are not limited to, silicon, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, germanium, germanium-containing, boron-containing, Ga/As, a flexible substrate, organic polymers, porous organic and inorganic materials, metals such as copper and aluminum, and diffusion barrier layers such as but not limited to TiN, Ti (C) N, TaN, Ta (C) N, Ta, W, or WN. The films are compatible with a variety of subsequent processing steps such as, for example, chemical mechanical planarization (CMP) and anisotropic etching processes.

The deposited films have applications, which include, but are not limited to, computer chips, optical devices, magnetic information storages, coatings on a supporting material or substrate, microelectromechanical systems (MEMS), nanoelectromechanical systems, thin film transistor (TFT), light emitting diodes (LED), organic light emitting diodes (OLED), IGZO, and liquid crystal displays (LCD). Potential use of resulting solid silicon oxide or carbon doped silicon oxide include, but not limited to, shallow trench insulation, inter layer dielectric, passivation layer, an etch stop layer, part of a dual spacer, and sacrificial layer for patterning.

The methods described herein provide a high quality silicon oxide, silicon nitride, silicon oxynitride, carbon doped silicon nitride, carbon doped silicon oxynitride, or carbon-doped silicon oxide film. The term “high quality” means a film that exhibits one or more of the following characteristics: a density of about 2.1 g/cc or greater, 2.2 g/cc or greater, 2.25 g/cc or greater; a wet etch rate that is 2.5 Å/s or less, 2.0 Å/s or less, 1.5 Å/s or less, 1.0 Å/s or less, 0.5 Å/s or less, 0.1 Å/s or less, 0.05 Å/s or less, 0.01 Å/s or less as measured in a solution of 0.5:100 of HF to water dilute HF (0.5 wt. % dHF) acid, an electrical leakage of about 1 or less e-8 A/cm² up to 6 MV/cm; a hydrogen impurity of about 5 e20 at/cc or less as measured by SIMS; and combinations thereof. With regard to the etch rate, a thermally grown silicon oxide film has 0.5 Å/s etch rate in 0.5 wt. % Hf.

In certain embodiments, one or more silicon precursor compound having Formulae A and/or B described herein can be used to form silicon- and oxygen-containing films as well as silicon- and nitrogen-containing films that are solid and are non-porous or are substantially free of pores.

The following examples illustrate the method for depositing silicon oxide films described herein and are not intended to limit the appended claims.

### EXAMPLES

### Example 1. Synthesis of 1-chloro-1,2,3,4,5,6-hexamethylcyclotrisilazane

Under the protection of nitrogen, acetyl chloride (31.4 g, 0.400 mol) was added dropwise over 1 hour to 1-dimethylamino-1,2,3,4,5,6-hexamethylcyclotrisilazane (100 g, 0.381 mol) at 5° C. while stirring. The reaction solution was allowed to warm slowly to room temperature. This reaction was repeated a second time, and the two reaction solutions were combined. The N, N-dimethylacetamide byproduct was removed under reduced pressure (1-2 torr, 20-35° C.), and the crude product was purified by vacuum distillation (1.0 Torr, 60-62° C.) to yield 159 g of +98% pure 1-chloro-1,2,3,4,5,6-hexamethylcyclotrisilazane. The normal boiling point was determined by differential scanning calorimetry (DSC) to be 230° C. Analysis by GC-MS showed the following mass peaks: m/z=253 (M+), 239, 219, 209, 195, 179, 165, 152, 145, 138, 131, 119, 102, 93, 86, 79, 72, 59, 45.

### Example 2. Synthesis of 1,3-dichloro-1,2,3,4,5,6-hexamethylcyclotrisilazane

Under the protection of nitrogen, acetyl chloride (30.6 g, 0.390 mol) was added dropwise over 1 hour to 1,3-bis(dimethylamino)-1,2,3,4,5,6-hexamethylcyclotrisilazane (56.7 g, 0.186 mol) at 5° C. while stirring. The reaction solution was allowed to warm slowly to room temperature. The N,N-dimethylacetamide byproduct was removed under dynamic vacuum at room temperature, and the crude product was purified by vacuum distillation (0.4 Torr, 52-54° C.) to yield 39.6 g of 1,3-dichloro-1,2,3,4,5,6-hexamethylcyclotrisilazane. The normal boiling point was determined by differential scanning calorimetry (DSC) to be 256° C. Analysis by GC-MS showed the following mass peaks: m/z=287 (M+), 273, 252, 244, 230, 210, 199, 179, 166, 152, 145, 138, 131, 122, 106, 93, 86, 79, 72, 59, 45.

### Example 3. Synthesis of 1,3,5-trichloro-1,3,5-trimethylcyclotrisilazane

A mixture of hexamethyldisilazane (5.0 g, 0.031 g), trichloromethylsilane (23.2 g, 0.155 mol), and FeCl₃ (0.05 g, 0.0003 mol) was stirred in a 40 mL scintillation vial for 3 days at room temperature. The resulting reaction mixture was filtered to remove solids, and the filtrate was determined by GC-MS analysis to contain unreacted trichloromethylsilane as well as the following products: chlorotrimethylsilane (major), 1,1-dichloro-1,3,3,3-tetramethyldisilazane (major), 1,1,3,3-tetrachloro-1,3-dimethyldisilazane (major), 1,3,5-trichloro-1,3,5-trimethylcyclotrisilazane (minor). GC-MS showed the following mass peaks for 1,3,5-trichloro-1,3,5-trimethylcyclotrisilazane: m/z=281 (M+), 266 (M-15), 246, 228, 214, 200, 192, 180, 171, 162, 151, 142, 137, 125, 115, 107, 101, 93, 86, 70, 63, 44.

### Example 4. Synthesis of 1-bromo-1,2,3,4,5,6-hexamethylcyclotrisilazane

Under the protection of nitrogen, acetyl bromide (0.48 g, 0.0039 mol) was added dropwise to 1-dimethylamino-1,2,3,4,5,6-hexamethylcyclotrisilazane (1.00 g, 0.00381 mol) at room temperature while stirring. After stirring for an additional 30 minutes, the reaction solution was analyzed by GC-MS and found to contain 1-bromo-1,2,3,4,5,6-hexamthylcyclotrisilazane as the major product. GC-MS showed the following mass peaks: m/z=297 (M+), 285, 268, 255, 239, 219, 212, 196, 182, 175, 160, 145, 132, 118, 102, 86, 72, 59, 45.

### Example 5. Synthesis of 1,3-dibromo-1,2,3,4,5,6-hexamethylcyclotrisilazane

Under the protection of nitrogen, acetyl bromide (0.84 g, 0.0068 mol) was added dropwise to 1,3-bis(dimethylamino)-1,2,3,4,5,6-hexamethylcyclotrisilazane (1.00 g, 0.00327 mol) at room temperature while stirring. After stirring for an additional 1 hour, the reaction solution was analyzed by GC-MS and found to contain 1,3-dibromo-1,2,3,4,5,6-hexamthylcyclotrisilazane among several other products. GC-MS showed the following mass peaks: m/z=377 (M+), 371, 357, 341, 329, 313, 299, 285, 270, 256, 242, 235, 219, 206, 192, 178, 165, 146, 132, 118, 104, 86, 72, 55, 41.

### Example 6. Synthesis of 1-iodo-1,2,3,4,5,6-hexamethylcyclotrisilazane

Under the protection of nitrogen, a 50 wt. % solution of acetyl iodide (0.65 g, 0.0038 mol) in Et₂O was added dropwise to a stirred solution of 1-dimethylamino-1,2,3,4,5,6-hexamethylcyclotrisilazane (1.00 g, 0.00381 mol) in Et₂O (1 mL) at room temperature. After stirring for 30 minutes, the reaction solution was analyzed by GC-MS and found to contain 1-iodo-1,2,3,4,5,6-hexamethylcyclotrisilazane. GC-MS showed the following mass peaks: m/z=345 (M+), 331, 316, 301, 287, 271, 257, 244, 230, 219, 203, 189, 175, 159, 159, 145, 131, 118, 102, 86, 72, 59, 45.

### Example 7. Synthesis of 1-chlorosilyl-2,2,4,4,6,6-hexamethylcyclotrisilazane

Under the protection of nitrogen, a solution of n-butyllithium (2.5 M in hexanes, 140 mL, 0.35 mol) was added dropwise via addition funnel to a stirred solution of 2,2,4,4,6,6-hexamethylcyclotrisilazane (100 g, 0.456 mol) in hexanes (100 mL) at 0° C. over 90 minutes. The reaction mixture was allowed to stir while warming to room temperature. Then, approximately 50 mL Et₂O was added, and the resulting solution was added dropwise via addition funnel to a stirred solution of dichlorosilane (25 wt. % in heptane, 184 g, 0.455 mol) at −30° C. over 2 hours. The resulting white slurry was allowed to stir while warming slowly to room temperature. The white solids were removed by filtration and the volatiles were removed under reduced pressure (5 Torr). The resulting crude concentrated liquid was found to contain 1-chlorosilyl-2,2,4,4,6,6-hexamethylcyclotrisilazane by GC-MS analysis. GC-MS showed the following mass peaks: m/z=282 (M−1), 268, 252, 232, 223, 216, 208, 194, 188, 174, 160, 150, 143, 136, 130, 116, 100, 93, 86, 79, 73, 59, 45.

### Example 8. Synthesis of 1-chloromethylsilyl-2,2,4,4,6,6-hexamethylcyclotrisilazane

Under the protection of nitrogen, a 50 wt. % solution of dichloromethylsilane (0.35 g, 0.0030 mol) in hexanes was added dropwise to a stirred solution of 2,2,4,4,6,6-hexamethylcyclotrisilazane (2.00 g, 0.00911 mol) and triethylamine (0.62 g, 0.0061 mol) in hexanes (7 mL). After stirring for 3 hours, the white slurry was filtered to remove the solids and the resulting solution was analyzed by GC-MS and found to contain the desired product, 1-chloromethylsilyl-2,2,4,4,6,6-hexamethylcyclotrisilazane. GC-MS showed the following mass peaks: m/z=297 (M+), 283, 267, 247, 231, 208, 194, 189, 174, 158, 151, 141, 131, 116, 100, 93, 86, 79, 73, 59, 45.

### Example 9. Synthesis of 1-chlorodimethylsilyl-2,2,4,4,6,6-hexamethylcyclotrisilazane

Under the protection of nitrogen, a solution of lithium-2,2,4,4,6,6-hexamethylcyclotrisilazane (0.60 g, 0.0027 mol) in toluene (3 mL) and THF (0.1 mL) was added dropwise to a stirred solution of dichlorodimethylsilane (0.39 g, 0.0030 mol) in hexanes (5 mL) at room temperature. After 1 hour of additional stirring, the mixture was filtered to remove the white solids. The filtrate was analyzed by GC-MS and found to contain the desired product, 1-chlorodimethylsilyl-2,2,4,4,6,6-hexamethylcyclotrisilazane. GC-MS showed the following mass peaks: m/z=311 (M+), 297, 281, 261, 245, 228, 224, 209, 189, 172, 157, 150, 141, 131, 115, 100, 93, 86, 73, 59, 45.

### Example 10. Synthesis of 1-dichloromethylsilyl-2,2,4,4,6,6-hexamethylcyclotrisilazane

Under the protection of nitrogen, a 50 wt. % solution of trichloromethylsilane (0.45 g, 0.0030 mol) in hexanes was added dropwise to a stirred solution of 2,2,4,4,6,6-hexamethylcyclotrisilazane (2.00 g, 0.00911 mol) and triethylamine (0.62 g, 0.0061 mol) in hexanes (7 mL). After stirring overnight at room temperature, the reaction mixture was heated between 60-80° C. for 3 hours, then continued to stir overnight. The resulting white slurry was filtered to remove the solids. The filtrate was analyzed by GC-MS and found to contain the desired product, 1-dichloromethylsilyl-2,2,4,4,6,6-hexamethylcyclotrisilazane. GC-MS showed the following mass peaks: m/z=332 (M+), 317, 301, 281, 265, 245, 229, 209, 188, 172, 151, 131, 120, 115, 100, 93, 86, 73, 63, 45.

### Example 11. Synthesis of 1-dichlorosilyl-2,2,4,4,6,6-hexamethylcyclotrisilazane

Under the protection of nitrogen, a 50 wt. % solution of trichlorosilane (0.41 g, 0.0030 mol) in hexanes was added dropwise to a stirred solution of 2,2,4,4,6,6-hexamethylcyclotrisilazane (2.00 g, 0.00911 mol) and triethylamine (0.62 g, 0.0061 mol) in hexanes (7 mL). After stirring overnight at room temperature, the resulting white slurry was filtered to remove the solids. The filtrate was analyzed by GC-MS and found to contain the desired product, 1-dichlorosilyl-2,2,4,4,6,6-hexamethylcyclotrisilazane. GC-MS showed the following mass peaks: m/z=317 (M+), 305, 287, 267, 251, 244, 229, 224, 214, 209, 194, 188, 179, 173, 158, 150, 144, 131, 120, 115, 100, 93, 86, 73, 59, 43.

### Example 12. Synthesis of 1-trichlorosilyl-2,2,4,4,6,6-hexamethylcyclotrisilazane

Under the protection of nitrogen, a 50 wt. % solution of silicon tetrachloride (0.52 g, 0.0031 mol) in hexanes was added dropwise to a stirred solution of 2,2,4,4,6,6-hexamethylcyclotrisilazane (2.00 g, 0.00911 mol) and triethylamine (0.62 g, 0.0061 mol) in hexanes (7 mL). After stirring for 3 days at room temperature, the resulting white slurry was filtered to remove the solids. The filtrate was analyzed by GC-MS and found to contain the desired product, 1-trichlorosilyl-2,2,4,4,6,6-hexamethylcyclotrisilazane. GC-MS showed the following mass peaks: m/z=352 (M+), 339, 322, 301, 287, 265, 248, 228, 209, 193, 172, 162, 150, 143, 131, 122, 113, 100, 93, 86, 73, 63, 45.

Unless otherwise indicated for the following examples PEALD was performed on a commercial lateral flow reactor (300 mm PEALD tool manufactured by ASM) equipped with 13.56 MHz direct plasma capability. Argon gas was used to maintain reactor pressure. The thermal ALD process was performed on a commercial screening tool manufactured by Picosun. In both cases, precursors were liquids maintained in stainless steel bubblers and delivered to the chamber with Ar carrier gas. Unless otherwise indicated for the following examples thermal ALD process was performed on a commercial screening tool manufactured by Picosun. The silicon precursor was delivered to the chamber by Ar carrier gas with flow rate of 200 sccm. All gases (e.g., purge and reactant gas and precursor) were preheated to 100° C. prior to entering the deposition zone. Gases and precursor flow rates were controlled with ALD diaphragm valves with high-speed actuation.

All depositions reported in the examples were done on native oxide containing Si substrates. Thickness and refractive indices of the films were measured using a FilmTek 3000SE ellipsometer. The growth rate per cycle (GPC) is calculated by dividing the measured thickness of resulting silicon- and nitrogen-containing films by the number of total ALD/PEALD cycles.

### Example 13. Deposition of Silicon- and Nitrogen-Containing Films Using 1-chloro-1,2,3,4,5,6-hexamethylcyclotrisilazane

The silicon- and nitrogen-containing films were deposited using 1-chloro-1,2,3,4,5,6-hexamethylcyclotrisilazane as silicon precursor and NH₃ plasma under the process conditions in PEALD 300 mm reactor The silicon precursor was delivered from a stainless steel container at 100° C. Argon was used as carrier gas and set to 200 sccm. The susceptor temperature was set to 300° C.

TABLE 2
Deposition Parameters for PEALD Silicon- and Nitrogen-containing
Films Using 1-Chloro-1,2,3,4,5,6-Hexamethylcyclotrisilazane

| | | Parameters |
|---|---|---|
| Step 1 | Insert Si wafer to the reactor | |
| Step 2 | Stabilizing the reactor to reach | Argon flow: 500 sccm |
| | | Argon flow time: 900 s |
| | desired temperature | Reactor pressure: 2 Torr |
| Step 3 | Dose silicon precursor to the | Precursor pulse: 1 s |
| | reactor | Hold precursor: 15 s |
| | | Carrier gas: 200 sccm Ar |
| | | Reactor pressure: 2 Torr |
| Step 4 | Purge | Argon flow time: 10 s |
| | | Argon flow: 380 sccm |
| | | Reactor pressure: 2 Torr |
| Step 5 | Ammonia plasma | Argon flow: 380 sccm |
| | | NH₃ flow: 100 sccm |
| | | Plasma power: 500 W |
| | | Plasma time: 10 s |
| | | Reactor pressure: 2 Torr |
| Step 6 | Purge | Plasma off |
| | | Argon flow: 380 sccm |
| | | Argon flow time: 10 s |
| | | Reactor pressure: 2 Torr |
| Step 7 | Remove Si wafer from the | |
| | reactor | |

Steps 3 through 6 were repeated many times to get a desired thickness of silicon- and nitrogen-containing films. Film growth per cycle (GPC) was 0.16 Å/cycle. It has reflective index of 1.85. The composition of resulting films was analyzed by X-Ray Photoelectron Spectroscopy (XPS). Bulk film contains 40.8 at. % Si, 52.3 at. % N, 5 at. % O and 1.3 at. % C. The ratio of nitrogen to silicon is 1.28, very close to the ratio of 1.33 for stoichiometric silicon nitride with a formula of Si₃N₄, demonstrating the halide-functionalized cyclotrisilazanes having at least 3 silicon atoms and a Si₃N₃ 6-membered ring are suitable for resulting in stoichiometric silicon nitride. The deposited film has leakage density of 5E-9 A/cm² at 1 MV/cm. For comparison, a silicon- and nitrogen-containing film was deposited using SiCl₄ and NH₃ plasma using process parameters described in Table 2. The as deposited film had a leakage current density of 5E-5 A/cm² at 1 MV/cm which suggests much lower film quality than that from 1-chloro-1,2,3,4,5,6-hexamethylcyclotrisilazane.

### Example 14. Thermal ALD Deposition of Silicon- and Nitrogen-Containing Films Using 1,3-Dichloro-1,2,3,4,5,6-Hexamethylcyclotrisilazane and Ammonia

The silicon- and nitrogen-containing films was deposited using 1,3-dichloro-1,2,3,4,5,6-hexamethylcyclotrisilazane and NH₃ thermally in Picosun ALD screening tool. Precursor was delivered from stainless steel container at 100° C. Substrate temperature was set to 600° C. The ALD steps are described in Table 3.

TABLE 3
Process for Thermal Atomic Layer Deposition of Silicon- and
Nitrogen-containing Films Using Picosun ALD Screening Tool

| | | | |
|---|---|---|---|
| Step 1 | | Insert 200 mm Si wafer | Chamber pressure |
| | | into reactor | <100 mT |
| Step 2 | | Evacuate reactor and | Chamber pressure |
| | | stabilized to reach desired | <100 mT |
| | | temperature | |
| Step 3 | 10 sec | Purge reactor with argon | Flow 200 sccm Ar |
| Step 4 | 5 sec | Dose Si precursor to the | Chamber pressure = 2.2 |
| | | reactor | Torr |
| Step 5 | 10 sec | Purge reactor with argon | Flow 200 sccm Ar |
| Step 6 | 14 sec | Dose nitrogen source | Chamber pressure = 2.2 |
| | | | Torr |
| Step 7 | 10 sec | Purge reactor with argon | Flow 200 sccm Ar |
| Step 8 | | Remove Si wafer from the | |
| | | reactor | |

Steps 4 through 7 were repeated multiple times to get a desired thickness. The resulting silicon- and nitrogen-containing films were deposited with a GPC of 0.12 Å/cycle.

### Example 15. Deposition of Silicon- and Nitrogen-Containing Films Using 1,3,5-trichloro-1,2,3,4,5,6-hexamethylcyclotrisilazane

The silicon- and nitrogen-containing film is deposited using 1,3,5-trichloro-1,2,3,4,5,6-hexamethylcyclotrisilazane as silicon precursor and NH₃ plasma under the process conditions in PEALD 300 mm reactor The silicon precursor is delivered from a stainless steel container at 100° C. Argon is employed as carrier gas with a flow rate of 200 sccm. The susceptor temperature is set to 300° C. Deposition is performed according to ALD steps and parameters listed on Table 2. Steps 3 through 6 are repeated many times to get a desired thickness of silicon- and nitrogen-containing film.

### Example 16. Thermal ALD Deposition of Si Containing Films Using 1,3,5-Trichloro-1,2,3,4,5,6-Hexamethylcyclotrisilazane and Ammonia

The silicon- and nitrogen-containing film is deposited using 1,3,5-trichloro-1,2,3,4,5,6-hexamethylcyclotrisilazane and ammonia with the Picosun ALD screening tool. Precursor is delivered from stainless steel container at 100° C. Process parameters is set to 600° C. Deposition is performed according to the ALD steps and parameters listed on Table 3.

Steps 4 through 7 are repeated multiple times to get desired thickness.

The foregoing description is intended primarily for purposes of illustration. Although the invention has been shown and described with respect to an exemplary embodiment thereof, it should be understood by those skilled in the art that the foregoing and various other changes, omissions, and additions in the form and detail thereof may be made therein without departing from the spirit and scope of the invention.

1. A silicon precursor compound selected from the group consisting of Formulae A and B: 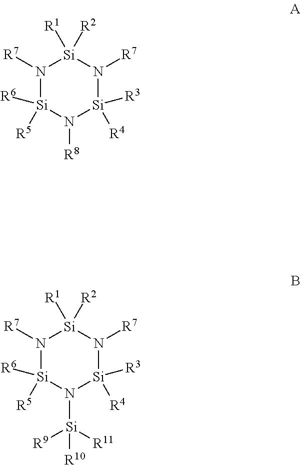
wherein R¹⁻⁶ are each independently selected from the group consisting of hydrogen, methyl, and a halide; R⁷ and R⁸ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, and a C₄₋₁₀ heterocyclic group; R⁹⁻¹¹ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, a C₄₋₁₀ heterocyclic group, and a halide, wherein two or more of substituents R¹⁻¹¹ may or may not be linked to form a substituted or unsubstituted, saturated or unsaturated, cyclic group, wherein at least one of the substituents R¹⁻⁶ in Formula A is a halide, wherein R⁷ and R⁸ in Formula A cannot both be hydrogen, and wherein at least one of the substituents R⁹⁻¹¹ in Formula B is a halide.

2. The compound of claim 1, wherein the at least one silicon precursor compound comprises at least one selected from the group consisting of 1-chlorosilyl-2,2,4,4,6,6-hexamethylcyclotrisilazane, 1-bromosilyl-2,2,4,4,6,6-hexamethylcyclotrisilazane, 1-iodosilyl-2,2,4,4,6,6-hexamethylcyclotrisilazane, 1-dichlorosilyl-2,2,4,4,6,6-hexamethylcyclotrisilazane, 1-trichlorosilyl-2,2,4,4,6,6-hexamethylcyclotrisilazane, 1-chloromethylsilyl-2,2,4,4,6,6-hexamethylcyclotrisilazane, 1-chlorodimethylsilyl-2,2,4,4,6,6-hexamethylcyclotrisilazane, 1-dichloromethylsilyl-2,2,4,4,6,6-hexamethylcyclotrisilazane, 1-chloro-1,2,3,4,5,6-hexamethylcyclotrisilazane, 1,2-dichloro-1,2,3,4,5,6-hexamethylcyclotrisilazane, 1,3,5-trichloro-1,2,3,4,5,6-hexamethylcyclotrisilazane, 1,3,5-trichloro-2,4,6-trimethylcyclotrisilazane, 1,1,3,3,5,5-hexachloro-2,4,6-trimethylcyclotrisilazane, 1-chloro-2,4,6-triethylcyclotrisilazane, 1,3-dichloro-2,4,6-triethylcyclotrisilazane, 1,3,5-trichloro-2,4,6-triethylcyclotrisilazane, 1,1,3,3,5,5-hexachloro-2,4,6-triethylcyclotrisilazane, 1-chloro-2,4,6-tri-iso-propylcyclotrisilazane, 1,3-dichloro-2,4,6-tri-iso-propylcyclotrisilazane, 1,3,5-trichloro-2,4,6-tri-iso-propylcyclotrisilazane, 1,1,3,3,5,5-hexachloro-2,4,6-tri-iso-propylcyclotrisilazane, 1-bromo-1,2,3,4,5,6-hexamethylcyclotrisilazane, 1,3-dibromo-1,2,3,4,5,6-hexamethylcyclotrisilazane, 1,3,5-tribromo-1,2,3,4,5,6-hexamethylcyclotrisilazane, 1,3,5-tribromo-2,4,6-trimethylcyclotrisilazane, 1-iodo-1,2,3,4,5,6-hexamethylcyclotrisilazane, and 1,3-diiodo-1,2,3,4,5,6-hexamethylcyclotrisilazane.

3. A composition comprising at least one silicon precursor compound selected from the group consisting of Formulae A and B: 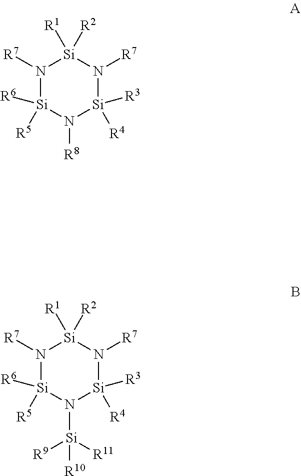
wherein R¹⁻⁶ are each independently selected from the group consisting of hydrogen, methyl, and a halide; R⁷ and R⁸ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, and a C₄₋₁₀ heterocyclic group; R⁹⁻¹¹ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, a C₄₋₁₀ heterocyclic group, and a halide, wherein two or more of substituents R¹⁻¹¹ may be linked to form a substituted or unsubstituted, saturated or unsaturated, cyclic group, wherein at least one of the substituents R¹⁻⁶ in Formula A is a halide, wherein R⁷ and R⁸ in Formula A cannot both be hydrogen, and wherein at least one of the substituents R⁹⁻¹¹ in Formula B is a halide.

4. The composition of claim 3 further comprising at least one purge gas.

5. The composition of claim 3 further comprising a solvent.

6. The composition of claim 3, wherein the at least one silicon precursor compound selected from Formulae A and B comprises at least one selected from the group consisting of 1-chlorosilyl-2,2,4,4,6,6-hexamethylcyclotrisilazane, 1-bromosilyl-2,2,4,4,6,6-hexamethylcyclotrisilazane, 1-iodosilyl-2,2,4,4,6,6-hexamethylcyclotrisilazane, 1-dichlorosilyl-2,2,4,4,6,6-hexamethylcyclotrisilazane, 1-trichlorosilyl-2,2,4,4,6,6-hexamethylcyclotrisilazane, 1-chloromethylsilyl-2,2,4,4,6,6-hexamethylcyclotrisilazane, 1-chlorodimethylsilyl-2,2,4,4,6,6-hexamethylcyclotrisilazane, 1-dichloromethylsilyl-2,2,4,4,6,6-hexamethylcyclotrisilazane, 1-chloro-1,2,3,4,5,6-hexamethylcyclotrisilazane, 1,2-dichloro-1,2,3,4,5,6-hexamethylcyclotrisilazane, 1,3,5-trichloro-1,2,3,4,5,6-hexamethylcyclotrisilazane, 1,3,5-trichloro-2,4,6-trimethylcyclotrisilazane, 1,1,3,3,5,5-hexachloro-2,4,6-trimethylcyclotrisilazane, 1-chloro-2,4,6-triethylcyclotrisilazane, 1,3-dichloro-2,4,6-triethylcyclotrisilazane, 1,3,5-trichloro-2,4,6-triethylcyclotrisilazane, 1,1,3,3,5,5-hexachloro-2,4,6-triethylcyclotrisilazane, 1-chloro-2,4,6-tri-iso-propylcyclotrisilazane, 1,3-dichloro-2,4,6-tri-iso-propylcyclotrisilazane, 1,3,5-trichloro-2,4,6-tri-iso-propylcyclotrisilazane, 1,1,3,3,5,5-hexachloro-2,4,6-tri-iso-propylcyclotrisilazane, 1-bromo-1,2,3,4,5,6-hexamethylcyclotrisilazane, 1,3-dibromo-1,2,3,4,5,6-hexamethylcyclotrisilazane, 1,3,5-tribromo-1,2,3,4,5,6-hexamethylcyclotrisilazane, 1,3,5-tribromo-2,4,6-trimethylcyclotrisilazane, 1-iodo-1,2,3,4,5,6-hexamethylcyclotrisilazane, and 1,3-diiodo-1,2,3,4,5,6-hexamethylcyclotrisilazane.

7. A method of depositing a silicon-containing film onto a substrate, the method comprising the steps of:
a) providing a substrate in a reactor;
b) introducing into the reactor at least one silicon precursor compound of claim 1;
c) purging the reactor with a purge gas;
d) introducing an oxygen-containing or nitrogen-containing source (or combination thereof) into the reactor; and
e) purging the reactor with a purge gas,
wherein steps b through e are repeated until a desired thickness of a film is deposited, and
wherein the method is conducted with the reactor at one or more temperatures ranging from about 25° C. to 600° C.

8. The method of claim 7, wherein the at least one silicon precursor compound is selected from the group consisting of 1-chlorosilyl-2,2,4,4,6,6-hexamethylcyclotrisilazane, 1-bromosilyl-2,2,4,4,6,6-hexamethylcyclotrisilazane, 1-iodosilyl-2,2,4,4,6,6-hexamethylcyclotrisilazane, 1-dichlorosilyl-2,2,4,4,6,6-hexamethylcyclotrisilazane, 1-trichlorosilyl-2,2,4,4,6,6-hexamethylcyclotrisilazane, 1-chloromethylsilyl-2,2,4,4,6,6-hexamethylcyclotrisilazane, 1-chlorodimethylsilyl-2,2,4,4,6,6-hexamethylcyclotrisilazane, 1-dichloromethylsilyl-2,2,4,4,6,6-hexamethylcyclotrisilazane, 1-chloro-1,2,3,4,5,6-hexamethylcyclotrisilazane, 1,2-dichloro-1,2,3,4,5,6-hexamethylcyclotrisilazane, 1,3,5-trichloro-1,2,3,4,5,6-hexamethylcyclotrisilazane, 1,3,5-trichloro-2,4,6-trimethylcyclotrisilazane, 1,1,3,3,5,5-hexachloro-2,4,6-trimethylcyclotrisilazane, 1-chloro-2,4,6-triethylcyclotrisilazane, 1,3-dichloro-2,4,6-triethylcyclotrisilazane, 1,3,5-trichloro-2,4,6-triethylcyclotrisilazane, 1,1,3,3,5,5-hexachloro-2,4,6-triethylcyclotrisilazane, 1-chloro-2,4,6-tri-iso-propylcyclotrisilazane, 1,3-dichloro-2,4,6-tri-iso-propylcyclotrisilazane, 1,3,5-trichloro-2,4,6-tri-iso-propylcyclotrisilazane, 1,1,3,3,5,5-hexachloro-2,4,6-tri-iso-propylcyclotrisilazane, 1-bromo-1,2,3,4,5,6-hexamethylcyclotrisilazane, 1,3-dibromo-1,2,3,4,5,6-hexamethylcyclotrisilazane, 1,3,5-tribromo-1,2,3,4,5,6-hexamethylcyclotrisilazane, 1,3,5-tribromo-2,4,6-trimethylcyclotrisilazane, 1-iodo-1,2,3,4,5,6-hexamethylcyclotrisilazane, and 1,3-diiodo-1,2,3,4,5,6-hexamethylcyclotrisilazane.

9. The method of claim 7, wherein the oxygen-containing source is selected from the group consisting of ozone, an oxygen plasma, a plasma comprising oxygen and argon, a plasma comprising oxygen and helium, an ozone plasma, a water plasma, a nitrous oxide plasma, a carbon dioxide plasma, and combinations thereof.

10. The method of claim 7, wherein the nitrogen-containing source is selected from the group consisting of ammonia, hydrazine, monoalkylhydrazine, dialkylhydrazine, nitrogen, nitrogen/hydrogen, nitrogen/argon plasma, nitrogen/helium plasma, ammonia plasma, nitrogen plasma, nitrogen/hydrogen plasma, organic amines such as tert-butylamine, dimethylamine, diethylamine, isopropylamine, diethylamine plasma, dimethylamine plasma, trimethyl plasma, trimethylamine plasma, ethylenediamine plasma, and an alkoxyamine such as ethanolamine plasma and mixtures thereof.

11. The method of claim 7 wherein the oxygen-containing source and/or the nitrogen-containing source comprises plasma.

12. The method of claim 11 wherein the plasma is generated in situ.

13. The method of claim 11 wherein the plasma is generated remotely.

14. The method of claim 7 wherein a density of the film is about 2.1 g/cc or greater.

15. The method of claim 7 wherein the film further comprises carbon.

16. The method of claim 7 wherein a density of the film is about 1.8 g/cc or greater.

17. The method of claim 7 wherein a carbon content of the film is 0.5 atomic weight percent (at. %) as measured by X-ray photoelectron spectroscopy or greater.

18. The method of claim 7 wherein the film has a leakage current density of 5E-9 A/cm² or lower at 1 MV/cm.

19. A silicon-containing film formed by the method of claim 7.

20. A silicon-containing film formed by the method of claim 11.

21. A silicon precursor composition for vapor deposition of silicon-containing films selected from the group consisting of Formulae A and B: 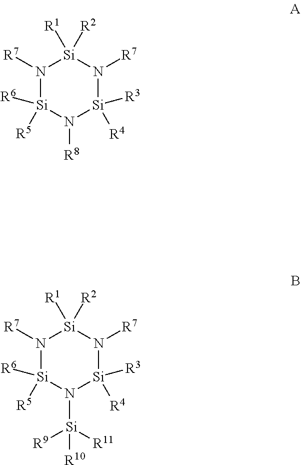
wherein R¹⁻⁶ are each independently selected from the group consisting of hydrogen, methyl, and a halide; R⁷ and R⁸ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, and a C₄₋₁₀ heterocyclic group; R⁹⁻¹¹ are each independently selected from the group consisting of hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aryl group, a C₄₋₁₀ heterocyclic group, and a halide, wherein two or more of substituents R¹⁻¹¹ may or may not be linked to form a substituted or unsubstituted, saturated or unsaturated, cyclic group, wherein at least one of the substituents R¹⁻⁶ in Formula A is a halide, wherein R⁷ and R⁸ in Formula A cannot both be hydrogen, and wherein at least one of the substituents R⁹⁻¹¹ in Formula B is a halide.
